(19) United States
(12) Patent Application Publication
(10) Pub. No.: US 2009/0244872 A1
(43) Pub. Date: Oct. 1, 2009

(54) SUPPORTING MECHANISM AND PORTABLE ELECTRONIC DEVICE USING SAME

(75) Inventor: FENG-QIAN YAN, Shenzhen City (CN)

Correspondence Address: PCE INDUSTRY, INC.;ATT. Steven Reiss, 288 SOUTH MAYO AVENUE, CITY OF INDUSTRY, CA, 91789, US

(73) Assignees: SHENZHEN FUTAIHONG PRECISION INDUSTRY CO., LTD., ShenZhen City (CN); FIH (HONG KONG) LIMITED, Kowloon (HK)

(21) Appl. No.: 12/212,752

(22) Filed: Sep. 18, 2008

(30) Foreign Application Priority Data
Mar. 28, 2008 (CN) 200810300785.9

(51) Int. Cl. H05K 7/00; F16H 19/04

(52) U.S. Cl. 361/807; 74/422

(57) ABSTRACT

A portable electronic device (100) is described including a housing (10) and a supporting mechanism (30) supporting the housing. The supporting mechanism includes a shaft (32) secured relative to the housing, a gear (34) rotatably secured with the shaft, a supporting rod (36) secured with the gear, and a rack (38) secured relative to the housing, and further relative to the gear and supporting rod by a meshing of the gear with the rack. The meshing can be changed to drive the supporting rod to rotate relative to the rack and the shaft along with a rotation of the gear about the shaft and along the rack.

### BACKGROUND

1. Field of the Invention

The invention relates to supporting mechanisms used in portable electronic devices.

2. Description of Related Art

With rapid development of information technology, portable electronic devices, such as cellular phones, personal digital assistant (PDA), and so on, are become more and more popular. The portable electronic device typically includes a display window and a supporting structure. The supporting structure is used to support the portable electronic device on a platform with a viewable angel for the display window. However, the supporting structure usually cannot be adjusted for adjusting the viewable angle of the display window.

Therefore, there is room for improvement within the art.

### BRIEF DESCRIPTION OF THE DRAWINGS

Many aspects of the exemplary supporting mechanism and a portable electronic device using the same can be better understood with reference to the following drawings. These drawings are not necessarily drawn to scale, the emphasis instead being placed upon clearly illustrating the principles of the exemplary supporting mechanism and the portable electronic device. Moreover, in the drawings like reference numerals designate corresponding parts throughout the several views. Wherever possible, the same reference numbers are used throughout the drawings to refer to the same or like elements of an embodiment.

FIG. 1 is an isometric and exploded view of a portable electronic device using a supporting mechanism according to the exemplary embodiment.

FIG. 2 is a partial view of the portable electronic device of FIG. 1, when assembled.

FIG. 3 is complete view of the portable electronic device of FIG. 1, when assembled.

FIG. 4 is a sectional view of the portable electronic device of FIG. 1, when assembled.

### DETAILED DESCRIPTION OF THE EXEMPLARY EMBODIMENTS

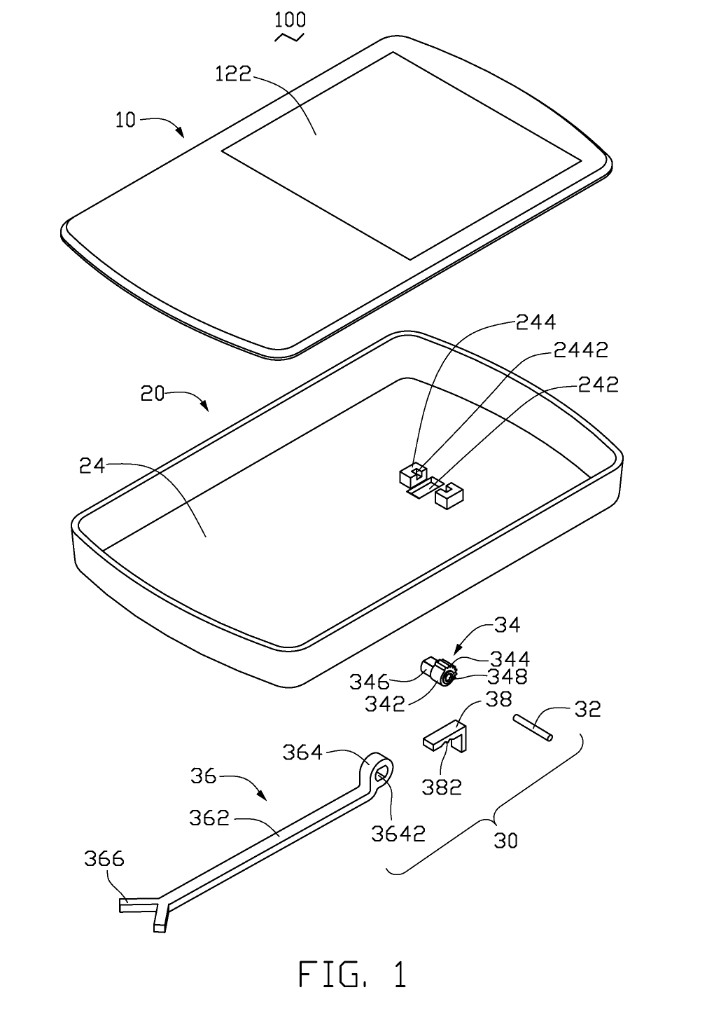

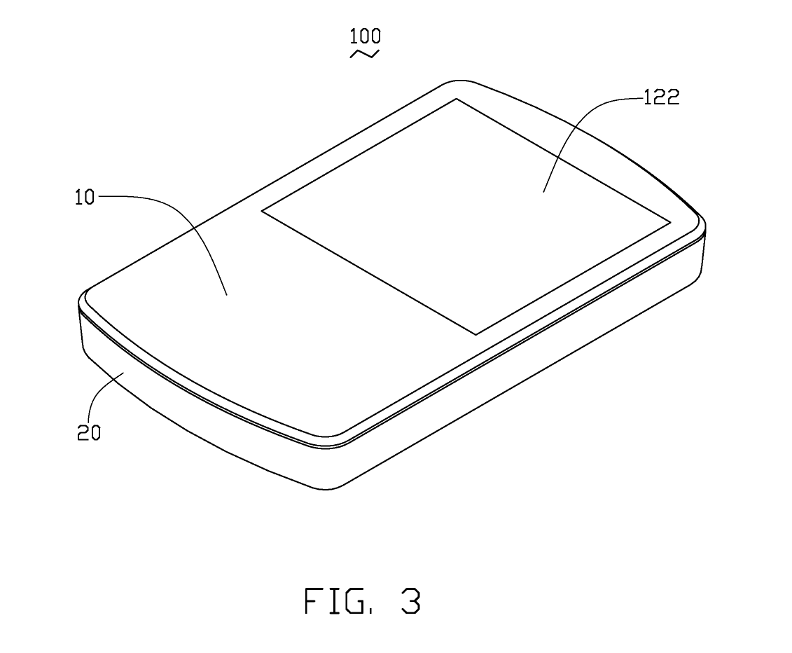

FIGS. 1 and 3 show a portable electronic device 100 (such as cellular phone) including an upper housing 10, a lower housing 20, and a supporting mechanism 30. The upper housing 10 engages with the lower housing 20 to define a space (not shown) for mounting electronic components.

The upper housing 10 has a display window 122. The lower housing 20 has a bottom wall 24. A through groove 242 passes through the bottom wall 24. Two shaft bulges 244 protrude on the bottom wall 24 and within the lower housing 20. The shaft bulges 244 are at opposite sides of the through groove 242 and aligned with each other. The shaft bulges 244 define two shaft notches 2442 facing toward and aligned with each other.

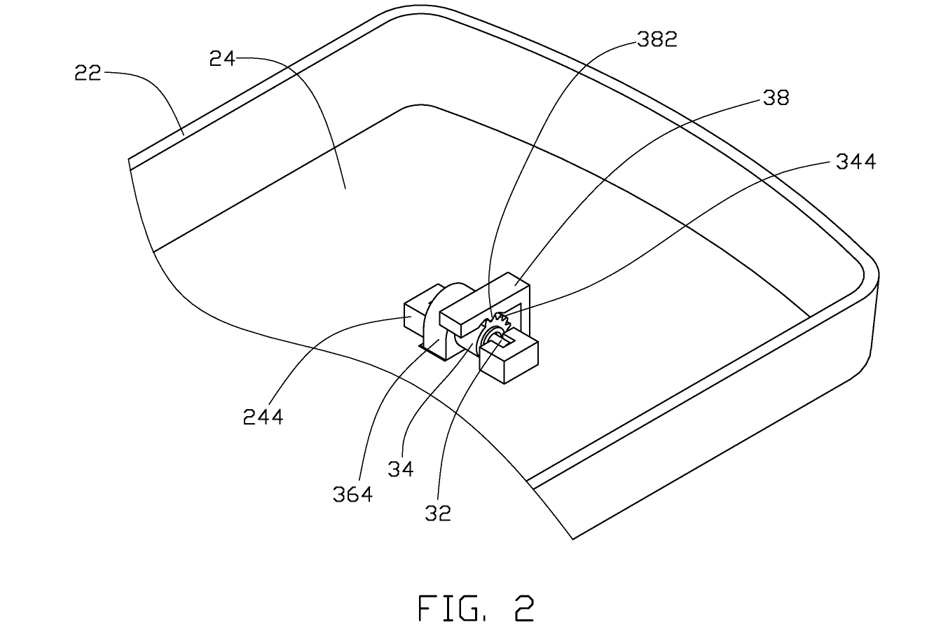

The supporting mechanism 30 includes a shaft 32, a gear 34, a supporting rod 36, and a rack 38. The shaft 32 is generally cylindrical and configured to be received and secured (e.g., hot-melted) into the two shaft notches 2442. When the shaft 32 is secured in the shaft notches 2442, the shaft 32 is positioned above the through groove 242 and within the lower housing 20 (seen in FIG. 2). The two shaft bulges 244 are connected with each other by the shaft 32.

The gear 34 is generally hollow cylinder including a gear portion 342 and a shaft portion 346. The gear portion 342 is generally cylindrical having a plurality of gear teeth 344 arranged on an exterior circumferential surface. The shaft portion 346 is generally deformed -cylinder shaped and extends from a side of the gear portion 342. The gear 34 defines a shaft hole 348 through the gear portion 342 and the shaft portion 346. The shaft hole 348 corresponds to the shaft 32 and has a substantially the same shape as and is slight larger than the shaft 32, to rotatably receive the shaft 32.

The supporting rod 36 is generally Y-shaped and has a body 362, a securing head 364, and two supporting feet 366. The body 362 connects the securing head 364 with the supporting feet 366. The securing head 364 is generally round and configured to pass through the through groove 242 (seen in FIG. 2). The securing head 364 defines a through slot 3642 corresponding to the shaft portion. The through slot 3642 has substantially the same shape and size as the shaft portion 346 and thus can receive and secure the shaft portion 346. The two supporting feet 366 are symmetrically arranged from the same end of the body 362. The supporting rod 36 can support the lower housing 20 combined with the upper housing 10 on a platform (e.g., a desk) by the supporting feet 366.

The rack 38 is generally an L-shaped bar formed with at least one rack tooth 382. The rack 38 is fixed (e.g., co-molded) on the bottom wall 24 with the rack tooth 382 above the shaft 32 for meshing with the gear teeth 344 (seen in FIG. 2).

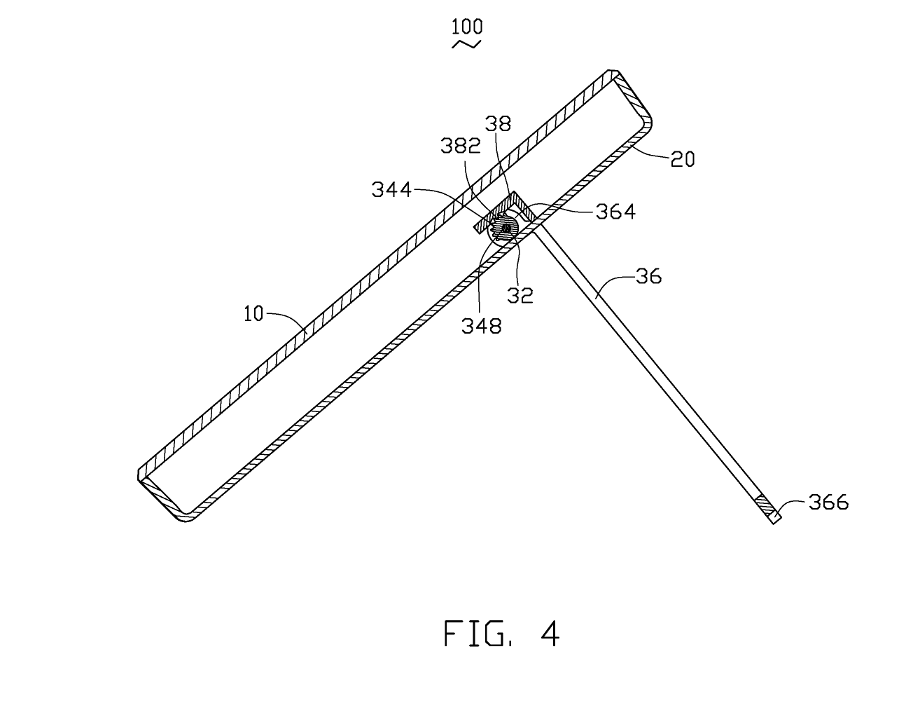

Referring to FIGS. 2 and 4, the supporting mechanism 30 is assembled to the lower housing 20. The gear 34 is rotatably secured with the shaft 32 by inserting the shaft 32 through the shaft hole 348. The gear teeth 344 mesh with the rack tooth 382. Thus, the gear 34 can rotate relative to the shaft 32 and secure at various positions by changing the meshing of the gear teeth 344 with the rack tooth 382. The securing head 364 passes through the through groove 242 and secured between the shaft bulges 244 by a securing of the shaft portion 346 inside the through slot 3642. Thus, the supporting rod 36 securely connects the gear 34 by the securing of the securing head 364 with the shaft portion 346. The supporting rod 36 can rotate pertinent to the gear 34.

FIG. 4 shows a supported position of the portable electronic device 100 relative to the platform (now shown) by the supporting mechanism 30. The portable electronic device 100 is supported for an easy view of the display window 122. The supporting feet 366 support the portable electronic device 100 above the platform with only one end of the lower housing 20 contacting the platform and the other opposite end of the lower housing 20 above the platform. The meshing of the gear teeth 344 with the rack tooth 382 maintains the supported position. The supported position can be adjusted by rotating the supporting rod 36. The rotation of the supporting rod 36 drives the rotation of the gear 34 about the shaft 32 and along the rack 38. Accordingly, the gear portion 342 rotates along the rack 38 and changes the meshing of the gear teeth 344 with the rack tooth 382. The portable electronic device 100 can be at another supported position by another meshing of the gear teeth 344 with the rack tooth 382.

It is to be understood, however, that even through numerous characteristics and advantages of the exemplary invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A supporting mechanism, comprising:
a shaft;
a gear rotatably connected with the shaft;
a supporting rod connected with the gear; and
a rack secured relative to the gear and the supporting rod by a meshing of the gear with the rack, the meshing being changed to drive the supporting rod to rotate relative to the rack and the shaft along with a rotation of the gear about the shaft and along the rack.

2. The supporting mechanism as claimed in claim 1, wherein the gear comprises a plurality of gear teeth, the rack comprises at least one rack tooth, and the rack tooth meshes with one of the gear teeth and can be adjusted to mesh with another one of the gear teeth by the rotation of the gear along the rack.

3. The supporting mechanism as claimed in claim 2, wherein the rotation of the gear about the shaft and along the rack is driven by a rotation of the supporting rod about the shaft.

4. The supporting mechanism as claimed in claim 3, wherein:
the gear comprises a gear portion and a shaft portion;
the plurality of gear teeth are arranged on the gear portion; and
the supporting rod defining a through slot securing the shaft portion therein.

5. The supporting mechanism as claimed in claim 4, wherein the gear defines a shaft hole through the gear portion and the shaft portion, the shaft hole rotatably securing the shaft therein.

6. The supporting mechanism as claimed in claim 4, wherein the supporting rod comprises a body, a securing head and a supporting foot, the body connecting the securing head with the supporting foot, the through slot defined through the securing head.

7. The supporting mechanism as claimed in claim 6, wherein the supporting rod further comprises another supporting foot, the two supporting feet arranged from the same end of the body, a combination of the two supporting feet and the body is generally Y-shaped.

8. The supporting mechanism as claimed in claim 2, wherein the rack is L-shaped around the gear, and the rack tooth is arranged above the gear.

9. A portable electronic device, comprising:
a housing;
a supporting mechanism supporting the housing, comprising:
a shaft secured relative to the housing;
a gear rotatably secured with the shaft;
a supporting rod secured with the gear; and
a rack secured relative to the housing, and further relative to the gear and supporting rod by a meshing of the gear with the rack, the meshing being changed to drive the supporting rod to rotate relative to the rack and the shaft along with a rotation of the gear about the shaft and along the rack.

10. The portable electronic device as claimed in claim 9, wherein:
the housing defines a through groove and comprises two bulges, the through groove positioned between the bulges;
the shaft secured on the bulges and above the through groove; and
the gear is secured between the bulges;
the supporting rod having a part passing through the through groove to be secured to the gear.

11. The portable electronic device as claimed in claim 10, wherein the rack is secured to the housing and adjacent to the budges.

12. The portable electronic device as claimed in claim 11, wherein the gear comprises a plurality of gear teeth, the rack comprises at least one rack tooth, and the rack tooth meshes with one of the gear teeth and can be adjusted to mesh with another one of the gear teeth by the rotation of the gear along the rack.

13. The portable electronic device as claimed in claim 12, wherein the rotation of the gear about the shaft and along the rack is drived by a rotation of the supporting rod about the shaft.

14. The portable electronic device as claimed in claim 13, wherein:
the gear comprises a gear portion and a shaft portion;
the plurality of gear teeth are arranged on the gear portion; and
the supporting rod defining a through slot securing the shaft portion therein.

15. The portable electronic device as claimed in claim 14, wherein the gear defines a shaft hole through the gear portion and the shaft portion, the shaft hole rotatably securing the shaft therein.

16. The portable electronic device as claimed in claim 14, wherein the supporting rod comprises a body, a securing head and a supporting foot, the body connecting the securing head with the supporting foot, the through slot defined through the securing head, the securing head passes through the through groove.

17. The portable electronic device as claimed in claim 15, wherein the supporting rod further comprises another supporting foot, the two supporting feet arranged from the same end of the body, a combination of the two supporting feet and the body is generally Y-shaped.

18. The portable electronic device as claimed in claim 11, wherein the rack is L-shaped around the gear, and the rack tooth is arranged above the gear.
